(19) United States
(12) Patent Application Publication
(10) Pub. No.: US 2011/0121886 A1
(43) Pub. Date: May 26, 2011

(54) CLOCK DETECTOR AND BIAS CURRENT CONTROL CIRCUIT

(75) Inventor: Young Deuk JEON, Daejeon (KR)

(73) Assignee: Electronics and Telecommunications Research Institute, Daejeon (KR)

(21) Appl. No.: 12/859,982

(22) Filed: Aug. 20, 2010

(30) Foreign Application Priority Data
Nov. 26, 2009 (KR) 10-2009-0115184

(51) Int. Cl. G11C 5/14; H03M 1/50

(52) U.S. Cl. 327/530; 341/166

(57) ABSTRACT

Provided are a clock detector and a bias current control circuit. The clock detector outputs a digital code corresponding to the frequency of an input clock, and the bias current control circuit controls a bias current supplied to an analog circuit according to the digital code output from the clock detector. Accordingly, when the clock detector and the bias current control circuit are used, it is possible to minimize the power consumption of an analog circuit by controlling a bias current supplied to an analog circuit according to a digital code corresponding to the frequency of an input clock.

### CROSS-REFERENCE TO RELATED APPLICATION

This application claims priority to and the benefit of Korean Patent Application No. 10-2009-0115184, filed Nov. 26, 2009, the disclosure of which is incorporated herein by reference in its entirety.

### BACKGROUND

1. Field of the Invention

The present invention relates to a clock detector and a bias current control circuit, and more particularly to a clock detector that outputs a digital code corresponding to the frequency of an input clock and a bias current control circuit that controls a bias current supplied to an analog circuit according to the digital code output from the clock detector.

2. Discussion of Related Art

With the increasing propagation of portable devices, universal chips having various functions are being used in the portable devices to reduce production costs.

In general, a universal chip is supplied with power supply voltage from the battery of a portable device, and uses different clock frequencies according to respective functions to minimize power consumption of the battery. In other words, a universal chip uses a high clock frequency for a function that needs to be performed at high speed and a low clock frequency for a standby state or simple function, thereby minimizing power consumption.

When such a universal chip is used in a digital circuit, it is possible to minimize the power consumption of the digital circuit without a specific technique because the digital circuit consumes power according to a clock frequency input from the universal chip.

On the other hand, when a universal chip is used in an analog circuit, the power consumption of the analog circuit needs to be controlled according to a clock frequency input from the universal chip because the analog circuit consumes uniform current regardless of the clock frequency input from the universal chip.

For this reason, the power consumption of an analog circuit is controlled by an additional control circuit according to a clock frequency. However, the additional control circuit hinders miniaturization of a product and deteriorates the price competitiveness.

### SUMMARY OF THE INVENTION

The present invention is directed to minimizing the power consumption of an analog circuit by generating a digital code corresponding to the frequency of an input clock and controlling a bias current supplied to the analog circuit according to the digital code.

One aspect of the present invention provides a clock detector including: a time-to-voltage converter (TVC) for converting a frequency of an input clock into an analog voltage and outputting the analog voltage; and an analog-to-digital converter (ADC) for converting the analog voltage corresponding to the frequency of the input clock into a digital code and outputting the digital code.

The TVC may include: a capacitor connected between a power supply voltage and a ground voltage; a current source connected in parallel to the capacitor; a first switch for connecting the capacitor to the power supply voltage according to a first clock; and a second switch for connecting the capacitor to the current source according to a second clock.

When the first switch is turned on by the first clock of high level, the power supply voltage may be connected to the capacitor, and charge may be charged in the capacitor, and when the second switch is turned on by the second clock of high level, the current source may be connected to the capacitor, and the charge charged in the capacitor may be discharged to the ground voltage.

The voltage Vout output from the TVC may be expressed by the following equation: Vout=VDD−(I_{S}×t)/C_{S}=VDD−{I_{S}×1/(2×Fck)}/C_{S} (where VDD denotes the power supply voltage, I_{S} denotes a current supplied from the current source, C_{S} denotes a capacitance of the capacitor, Fck denotes a frequency of the first and second clocks having a duty ratio of 50%, and t denotes a time for which the first and second clocks are maintained at high level), and have a sawtooth wave shape. Here, the lower the frequency of the first and second clocks, the larger sawtooth wave shape the voltage Vout output from the TVC may have.

The ADC may output a 3-bit digital code, and the digital code may have a value corresponding to the frequency of the input clock.

Another aspect of the present invention provides a bias current control circuit including: a variable bias current source for supplying a variable bias current to a first node according to a digital code input from the outside; first and second transistors for mirroring the variable bias current of the first node and transferring the mirrored variable bias current to a second node; and a bias voltage source for supplying a bias voltage corresponding to the mirrored variable bias current.

The digital code may be input from an external clock detector, and the clock detector may include: a TVC for converting a frequency of an input clock into an analog voltage and outputting the analog voltage; and an ADC for converting the analog voltage corresponding to the frequency of the input clock into a digital code and outputting the digital code.

The variable bias current source may include: a current source for supplying a minimum bias current; and a current source for supplying an additional bias current according to the digital code input from the outside. In an exemplary embodiment, the variable bias current source may include: first to fourth current sources connected in parallel; and first to third switches for respectively connecting the first to third current sources to the first node according to the digital code input from the outside. The first to third current sources may supply a bias current increasing as 3 bit binary digital codes.

The bias voltage source may include a third transistor whose gate and drain are connected to the second node and whose source is connected to a ground voltage, and the bias voltage corresponding to the mirrored variable bias current may be output from the gate of the third transistor.

### BRIEF DESCRIPTION OF THE DRAWINGS

The above and other objects, features and advantages of the present invention will become more apparent to those of ordinary skill in the art by describing in detail exemplary embodiments thereof with reference to the attached drawings, in which:

FIG. 1 is a circuit diagram of a clock detector according to an exemplary embodiment of the present invention;

FIG. 2 shows waveform diagrams of a voltage output from a time-to-voltage converter (TVC) shown in FIG. 1; and

FIG. 3 is a circuit diagram of a bias current control circuit according to an exemplary embodiment of the present invention.

### DETAILED DESCRIPTION OF EXEMPLARY EMBODIMENTS

Hereinafter, exemplary embodiments of the present invention will be described in detail. However, the present invention is not limited to the embodiments disclosed below but can be implemented in various forms. The following embodiments are described in order to enable those of ordinary skill in the art to embody and practice the present invention. To clearly describe the present invention, parts not relating to the description are omitted from the drawings. Like numerals refer to like elements throughout the description of the drawings.

Throughout this specification, when an element is referred to as being “connected” or “coupled” to another element, it can be directly connected or coupled to the other element or electrically connected or coupled to the other element with yet another element interposed between them.

Throughout this specification, when an element is referred to as “comprises,” “includes,” or “has” a component, it does not preclude another component but may further include the other component unless the context clearly indicates otherwise. Also, as used herein, the terms “ . . . unit,” “ . . . device,” “ . . . module,” etc., denote a unit of processing at least one function or operation, and may be implemented as hardware, software, or combination of hardware and software.

Prior to the description of exemplary embodiments of the present invention, the basic concept of the present invention will be described below in brief.

To control the power consumption of an analog circuit, a bias voltage supplied to the analog circuit needs to be changed. However, the bias voltage is an analog signal, and it is impossible to control the bias voltage using a clock having a digital value of 1 or 0. Thus, an analog signal corresponding to the frequency of an input clock should be detected from the input clock.

However, it is almost impossible to directly detect an analog signal corresponding to the frequency. Furthermore, even if an analog signal can be detected, it is difficult to obtain a stable analog signal due to noise such as a glitch.

Thus, in the present invention, a digital signal corresponding to the frequency of an input clock is detected from the input clock, and a bias current supplied to an analog circuit is controlled according to the detected digital signal, thereby minimizing the power consumption of the analog circuit. This is to be more clearly understood with reference to the following exemplary embodiments.

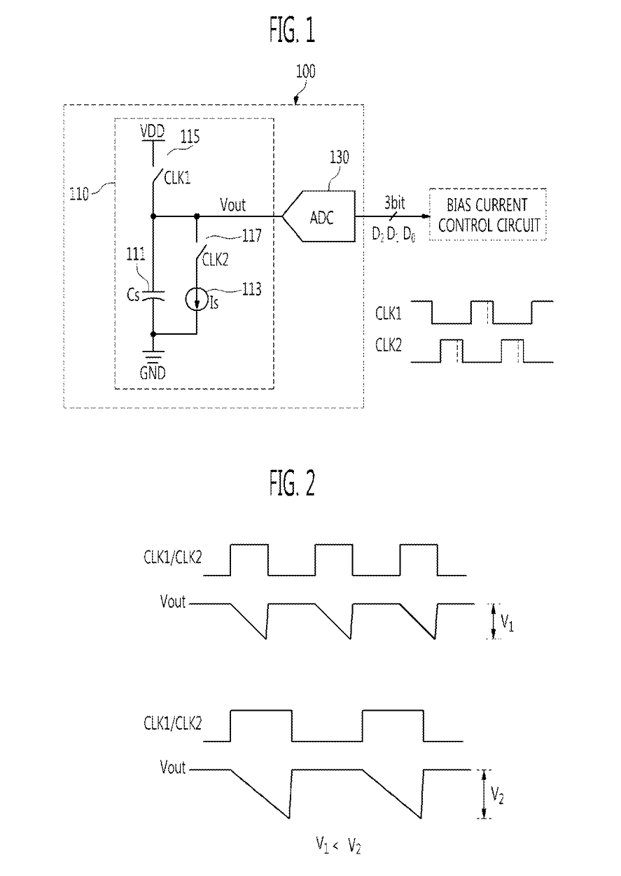

FIG. 1 illustrates a clock detector 100 according to an exemplary embodiment of the present invention.

Referring to FIG. 1, the clock detector 100 according to an exemplary embodiment of the present invention includes a time-to-voltage converter (TVC) 110 that converts the frequency of an input clock into an analog voltage and outputs the analog voltage, and an analog-to-digital converter (ADC) 130 that converts the analog voltage corresponding to the frequency of the input clock into a digital code and outputs the digital code.

The TVC 110 includes a capacitor 111 that is connected between a power supply voltage VDD and a ground voltage GND and has a capacitance C_{S}, a current source 113 that is connected in parallel to the capacitor and supplies a current I_{S}, a first switch 115 that connects the capacitor 111 to the power supply voltage VDD according to a first clock CLK1, and a second switch 117 that connects the capacitor 111 to the current source 113 according to a second clock CLK2.

Although it is described in this exemplary embodiment that the power supply voltage VDD is connected to the capacitor 111, a specific voltage other than the power supply voltage VDD may be connected to the capacitor 111.

The ADC 130 converts an analog voltage Vout applied to the capacitor 111 into a 3-bit digital code D₂D₁D₀ and outputs the 3-bit digital code D₂D₁D₀. According to applications, the number of output bits (resolution) of the ADC 130 can be changed.

Operation of the clock detector 100 having the above-described structure will be described in detail below.

First, the first switch 115 is turned on by the first clock CLK1 of high level, and the second switch 117 is turned off by the second clock CLK2 of low level.

When the first switch 115 is turned on, the power supply voltage VDD is connected to the capacitor 111, and charge is charged in the capacitor.

At this time, the charge Q charged in the capacitor 111 is expressed by the following Equation 1:

Q=C_{S}×(VDD−GND) [Equation 1]

Here, C_{S} denotes the capacitance of the capacitor 111, VDD denotes the power supply voltage, and GND denotes the ground voltage.

Subsequently, the first clock CLK1 becomes low level to turn off the first switch 115, and the second clock CLK2 becomes high level to turn on the second switch 117.

When the second switch 117 is turned on, the current source 113 is connected to the capacitor 111, and the charge charged in the capacitor 111 is discharged to the ground voltage GND.

At this time, the charge Q′ discharged from the capacitor 111 is expressed by the following Equation 2:

Q′=I_{S}×t [Equation 2]

Here, I_{S} denotes a current supplied from the current source 113, and t denotes a time for which the second clock CLK2 is maintained at high level, which is generally a half of a clock period when a clock has a duty ratio of 50%.

Thus, when the first and second clocks CLK1 and CLK2 have a first frequency Fck and a duty ratio of 50%, the voltage Vout output from the TVC 110 is expressed by the following Equation 3:

Vout=VDD−(I_{S}×t)/C_{S}=VDD−{I_{S}×1/(2×Fck)}/C_{S}

Here, VDD denotes the power supply voltage, I_{S} denotes the current supplied from the current source 113, C_{S} denotes the capacitance of the capacitor 111, Fck denotes a frequency of the first and second clocks CLK1 and CLK2 having a duty ratio of 50%, and t denotes a time for which the first and second clocks CLK1 and CLK2 are maintained at high level.

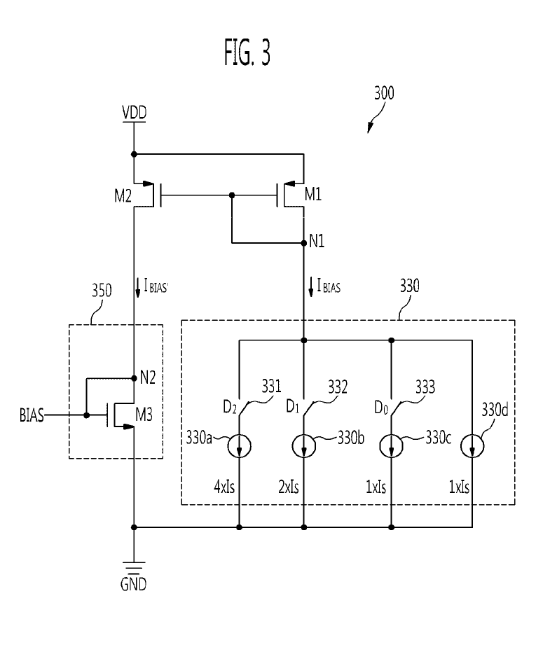

FIG. 2 shows waveform diagrams of a voltage output from the TVC 110.

As shown in FIG. 2, the voltage Vout output from the TVC 110 has a sawtooth wave shape due to charge and discharge caused by the first and second clocks CLK1 and CLK2.

Here, as the frequency of the first and second clocks CLK1 and CLK2 decreases, a discharge time increases, and thus the output voltage Vout has a larger sawtooth wave shape.

When the voltage Vout having a sawtooth wave shape is applied to the ADC 130, the ADC 130 converts the input voltage Vout into a 3-bit digital code D₂D₁D₀ and outputs the 3-bit digital code D₂D₁D₀.

Here, a large value of the digital code D₂D₁D₀ means that the first and second clocks CLK1 and CLK2 have a high frequency, and a small value of the digital code D₂D₁D₀ means that the first and second clocks CLK1 and CLK2 have a low frequency. In other words, the digital code D₂D₁D₀ has a value corresponding to the frequency of the first and second clocks CLK1 and CLK2.

Consequently, by controlling a bias current supplied to an analog circuit according to the digital code D₂D₁D₀, it is possible to minimize the power consumption of the analog circuit, which will be described in detail below.

FIG. 3 is a circuit diagram of a bias current control circuit 300 according to an exemplary embodiment of the present invention.

Referring to FIG. 3, the bias current control circuit 300 according to an exemplary embodiment of the present invention includes a variable bias current source 330 that supplies a variable bias current I_{BIAS} to a first node N1 according to a digital code D₂D₁D₀ input from the outside, first and second transistors M1 and M2 that mirror the variable bias current I_{BIAS} of the first node N1 and transfer the mirrored variable bias current I_{BIAS′} to a second node N2, and a bias voltage source 350 that supplies a bias voltage VT corresponding to the mirrored variable bias current I_{BIAS′}.

Here, the digital code D₂D₁D₀ may be input from the clock detector 100 shown in FIG. 1.

The variable bias current source 330 includes first to fourth current sources 330a to 330d connected in parallel, and first to third switches 331 to 333 respectively connecting the first to third current sources 330a to 330c to the first node N1 according to the digital code D₂D₁D₀ input from the outside.

The first to third current sources 330a to 330c supply bias currents of 4×I_{S}, 2×I_{S}, and 1×I_{S} to the first node N1 according to the input digital code D₂D₁D₀ respectively, and the fourth current source 330d supplies a bias current of 1×I_{S} to the first node.

In other words, the variable bias current source 330 may basically supply the bias current of 1×I_{S} by the fourth current source 330d, and additionally supply the bias currents of 4×I_{S}, 2×I_{S}, and 1×I_{S} by the first to third current sources 330a to 330c.

For example, when the digital code of D₂D₁D₀ “000” is input from the outside, all of the first to third switches 331 to 333 are turned off, and the variable bias current source 330 supplies the bias current of 1×I_{S}. When the digital code of D₂D₁D₀ “111” is input, all of the first to third switches 331 to 333 are turned on, and the variable bias current source 330 supplies the bias current of 8×I_{S}.

In this exemplary embodiment of the present invention, a variable bias current source is configured according to a binary method in which a bias current increases as 3 bit binary digital codes. However, the structure of the variable bias current source can be changed according to applications.

The gates of the first and second transistors M1 and M2 are connected in common to the first node N1, the drains are connected in common to a power supply voltage VDD, and the sources are connected to the first node N1 and the second node N2, respectively. In other words, the first and second transistors M1 and M2 form a current mirror.

When the first and second transistors M1 and M2 have the same size, the variable bias current I_{BIAS} and the mirrored variable bias current I_{BIAS′} have the same value.

The bias voltage source 350 includes a third transistor M3, and the bias voltage VT corresponding to the mirrored variable bias current I_{BIAS′} is output from the gate of the third transistor M3. Here, the drain and gate of the third transistor M3 are connected in common to the second node N2, and the source is connected to a ground terminal GND.

As described above, using the clock detector 100 and the bias current control circuit 300 according to exemplary embodiments of the present invention, it is possible to control a bias current supplied to an analog circuit according to a digital code corresponding to the frequency of an input clock and thereby minimize the power consumption of the analog circuit. As a result, the lifespan of a battery can be extended.

In an exemplary embodiment of the present invention, a digital code corresponding to the frequency of an input clock is generated, and a bias current supplied to an analog circuit is controlled according to the digital code. Thus, it is possible to minimize the power consumption of the analog circuit and thereby extend the lifespan of a battery.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A clock detector, comprising:
a time-to-voltage converter (TVC) for converting a frequency of an input clock into an analog voltage and outputting the analog voltage; and
an analog-to-digital converter (ADC) for converting the analog voltage corresponding to the frequency of the input clock into a digital code and outputting the digital code.

2. The clock detector of claim 1, wherein the TVC includes:
a capacitor connected between a power supply voltage and a ground voltage;
a current source connected in parallel to the capacitor;
a first switch for connecting the capacitor to the power supply voltage according to a first clock; and
a second switch for connecting the capacitor to the current source according to a second clock.

3. The clock detector of claim 2, wherein when the first switch is turned on by the first clock of high level, the power supply voltage is connected to the capacitor, and charge is charged in the capacitor, and
when the second switch is turned on by the second clock of high level, the current source is connected to the capacitor, and the charge charged in the capacitor is discharged to the ground voltage.

4. The clock detector of claim 3, wherein the voltage Vout output from the TVC is expressed by the following equation:
Vout=VDD−(I_{S}×t)/C_{S}=VDD−{I_{S}×1/(2×Fck)}/C_{S}
(where VDD denotes the power supply voltage, I_{S} denotes a current supplied from the current source, C_{S} denotes a capacitance of the capacitor, Fck denotes a frequency of the first and second clocks having a duty ratio of 50%, and t denotes a time for which the first and second clocks are maintained at high level).

5. The clock detector of claim 4, wherein the voltage Vout output from the TVC has a sawtooth wave shape, and has a larger sawtooth wave shape as the frequency of the first and second clocks decreases.

6. The clock detector of claim 5, wherein the ADC outputs a 3-bit digital code, and the digital code has a value corresponding to the frequency of the input clock.

7. A bias current control circuit, comprising:
a variable bias current source for supplying a variable bias current to a first node according to a digital code input from the outside;
first and second transistors for mirroring the variable bias current of the first node and transferring the mirrored variable bias current to a second node; and
a bias voltage source for supplying a bias voltage corresponding to the mirrored variable bias current.

8. The bias current control circuit of claim 7, wherein the digital code is input from an external clock detector, and
the clock detector includes:
a time-to-voltage converter (TVC) for converting a frequency of an input clock into an analog voltage and outputting the analog voltage; and
an analog-to-digital converter (ADC) for converting the analog voltage corresponding to the frequency of the input clock into a digital code and outputting the digital code.

9. The bias current control circuit of claim 7, wherein the variable bias current source includes:
a current source for supplying a minimum bias current; and
a current source for supplying an additional bias current according to the digital code input from the outside.

10. The bias current control circuit of claim 9, wherein the variable bias current source includes:
first to fourth current sources connected in parallel; and
first to third switches for respectively connecting the first to third current sources to the first node according to the digital code input from the outside.

11. The bias current control circuit of claim 10, wherein the first to third current sources supply a bias current increasing as 3 bit binary digital codes.

12. The bias current control circuit of claim 7, wherein the bias voltage source includes a third transistor whose gate and drain are connected to the second node and whose source is connected to a ground voltage, and the bias voltage corresponding to the mirrored variable bias current is output from the gate of the third transistor.
